(19) United States
(12) Patent Application Publication
(10) Pub. No.: US 2025/0150732 A1
(43) Pub. Date: May 8, 2025

(54) PHOTODETECTION DEVICE

(71) Applicant: KYOCERA Corporation, Kyoto-shi, Kyoto (JP)

(72) Inventors: Eiji KANDA, Yasu-shi, Shiga (JP); Nobuyuki SHIMA, Otsu-shi, Shiga (JP); Shigeki KITAMURA, Hikone-shi, Shiga (JP)

(21) Appl. No.: 18/838,129

(22) PCT Filed: Feb. 20, 2023
(86) PCT No.: PCT/JP2023/006080

§ 371 Date: Aug. 13, 2024

(30) Foreign Application Priority Data
Feb. 21, 2022 (JP) 2022-025043

(51) Int. Cl. H04N 25/77; H04N 25/709

(52) U.S. Cl. CPC H04N 25/77; H04N 25/709

(57) ABSTRACT

A photodetection device includes a substrate, multiple pixels, power lines, readout signal lines, and reset signal lines. Each pixel includes a photodiode including a cathode electrode, an amplifier transistor including a gate connected to the cathode electrode, an input connected to one of the power lines, and an output connected to one of the readout signal lines, a reset transistor including a gate connected to one of the reset signal lines, an input connected to the one power line, and an output connected to the cathode electrode and the gate of the amplifier transistor, and a first contact hole extending in a thickness direction of a substrate and connecting the cathode electrode to the gate of the amplifier transistor and to the output of the reset transistor. The first contact hole is between the amplifier transistor and the reset transistor in a direction in which the one power line extends.

### TECHNICAL FIELD

The present disclosure relates to a photodetection device.

### BACKGROUND OF INVENTION

A known photodetection device is described in, for example, Patent Literature 1.

### CITATION LIST

### Patent Literature

Patent Literature 1: Japanese Unexamined Patent Application Publication No. 11-307756

Patent Literature 2: Japanese Unexamined Patent Application Publication No. 11-186561

### SUMMARY

In an aspect of the present disclosure, a photodetection device includes a substrate, a plurality of pixels, a plurality of power lines, a plurality of readout signal lines, and a plurality of reset signal lines. The plurality of pixels is in rows and columns on the substrate. The plurality of power lines is each located for a corresponding column of the columns of the plurality of pixels. The plurality of readout signal lines is each located for a corresponding column of the columns of the plurality of pixels. The plurality of readout signal lines reads voltage signals generated respectively by the plurality of pixels. The plurality of reset signal lines is each located for a corresponding row of the rows of the plurality of pixels. Each of the plurality of reset signal lines resets voltage signals from pixels of the plurality of pixels in a corresponding row of the rows. Each of the plurality of pixels includes a first insulating layer, a photodiode, an amplifier transistor, a reset transistor, and a contact hole. The first insulating layer is on the substrate. The photodiode is on a second surface of the first insulating layer. The second surface is opposite to a first surface of the first insulating layer facing the substrate. The photodiode includes a semiconductor layer, an anode electrode, and a cathode electrode. The amplifier transistor is between the substrate and the first insulating layer. The amplifier transistor includes a gate electrode connected to the cathode electrode, an input electrode connected to one power line of the plurality of power lines, and an output electrode connected to one readout signal line of the plurality of readout signal lines. The reset transistor is between the substrate and the first insulating layer. The reset transistor includes a gate electrode connected to one reset signal line of the plurality of reset signal lines, an input electrode connected to the one power line, and an output electrode connected to the cathode electrode and the gate electrode of the amplifier transistor. The contact hole extends through the first insulating layer in a thickness direction and connects the cathode electrode to the gate electrode of the amplifier transistor and to the output electrode of the reset transistor. The contact hole is located between the amplifier transistor and the reset transistor in a direction in which the one power line extends.

In another aspect of the present disclosure, a photodetection device includes a substrate, a plurality of pixels, a plurality of power lines, a plurality of readout signal lines, a plurality of reset signal lines, and a plurality of select signal lines. The plurality of pixels is in rows and columns on the substrate. The plurality of power lines is each located for a corresponding column of the columns of the plurality of pixels. The plurality of readout signal lines is each located for a corresponding column of the columns of the plurality of pixels. The plurality of readout signal lines reads voltage signals generated respectively by the plurality of pixels. The plurality of reset signal lines is each located for a corresponding row of the rows of the plurality of pixels. Each of the plurality of reset signal lines resets voltage signals from pixels of the plurality of pixels in a corresponding row of the rows. The plurality of select signal lines is each located for a corresponding row of the rows of the plurality of pixels. The plurality of select signal lines sets readout periods for the respective voltage signals. Each of the plurality of pixels includes a photodiode, an amplifier transistor, a reset transistor, and a select transistor. The photodiode includes an anode electrode and a cathode electrode. The amplifier transistor includes a gate electrode connected to the cathode electrode and an input electrode connected to one power line of the plurality of power lines. The reset transistor includes a gate electrode connected to one reset signal line of the plurality of reset signal lines, an input electrode connected to the one power line, and an output electrode connected to the cathode electrode and the gate electrode of the amplifier transistor. The select transistor includes a gate electrode connected to one select signal line of the plurality of select signal lines, an input electrode connected to the output electrode of the amplifier transistor, and an output electrode connected to one readout signal line of the plurality of readout signal lines. The amplifier transistor includes a channel overlapping the one power line in a plan view. The select transistor includes a channel overlapping the one readout signal line in a plan view. The reset transistor includes a channel overlapping at least one of the one power line or a wiring layer connected to the anode electrode or the cathode electrode.

### BRIEF DESCRIPTION OF THE DRAWINGS

The objects, features, and advantages of the present disclosure will become more apparent from the following detailed description and the drawings.

FIG. 1 is a block diagram of a photodetection device according to an embodiment of the present disclosure.

FIG. 2 is a circuit diagram of each pixel in the photodetection device in FIG. 1.

FIG. 3 is a plan view of each pixel in the photodetection device in FIG. 1.

FIG. 4 is a cross-sectional view taken along section line IV-IV in FIG. 3.

FIG. 5 is a cross-sectional view taken along section line V-V in FIG. 3.

### DESCRIPTION OF EMBODIMENTS

A variety of photodetection devices have been suggested to use photoelectric conversion elements such as photodiodes to detect light. For example, Patent Literatures 1 and 2 each describe a photodetection device including multiple pixels that convert electric charge generated in a photodiode to a voltage signal.

In known photodetection devices, elements such as transistors in a pixel may not be arranged efficiently, causing the pixel pitch to be large. In known photodetection devices, electric fields generated in photodiodes may affect the operation of the transistors and cause fluctuations in voltage signals. Thus, known photodetection devices are to have improved definition and detection accuracy.

A photodetection device according to the present disclosure will now be described with reference to the drawings. Each figure referred to below illustrates main components and other elements of the photodetection device according to one or more embodiments of the present disclosure. In the embodiments of the present disclosure, the photodetection device may include known components that are not illustrated, for example, circuit boards, wiring conductors, control ICs, and LSI circuits. Each figure referred to below is also schematic and is not necessarily drawn to scale relative to, for example, the actual shapes and dimensional ratios of components of the photodetection device.

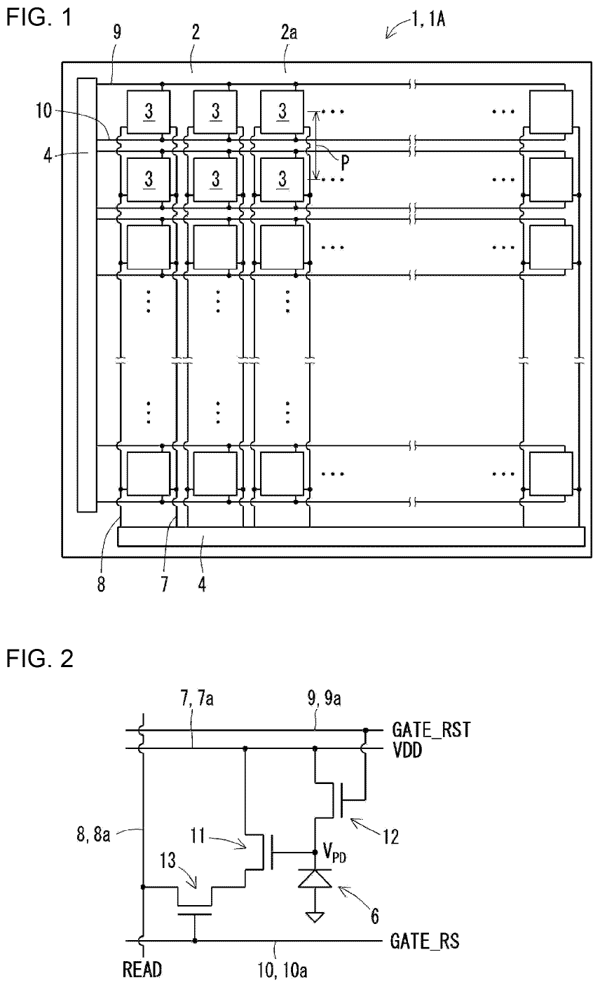

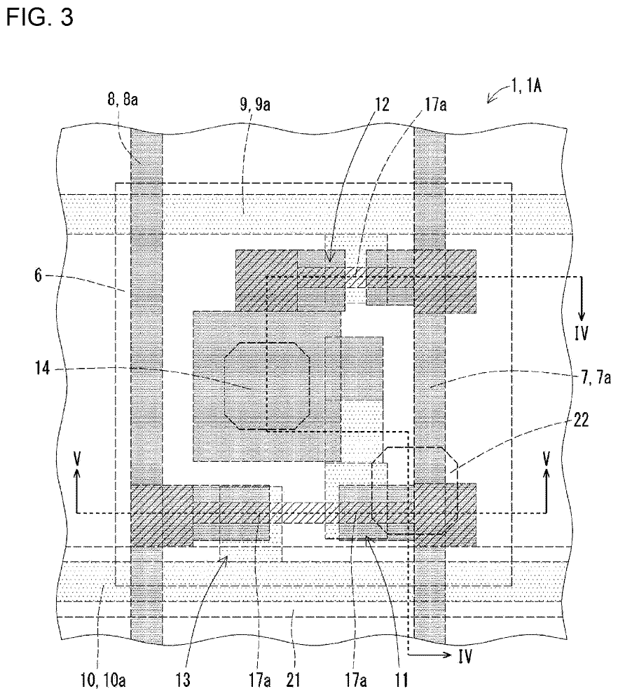

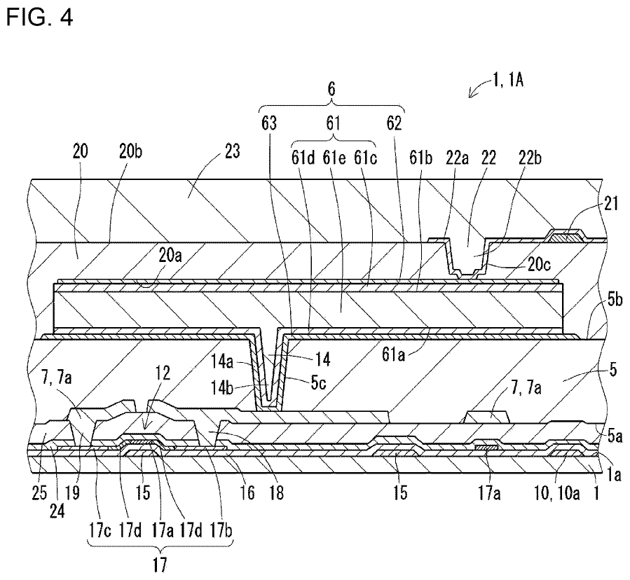

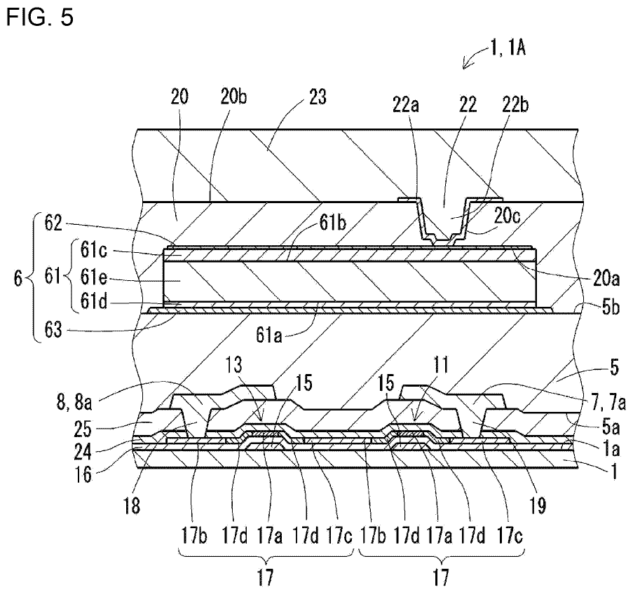

FIG. 1 is a block diagram of a photodetection device according to an embodiment of the present disclosure. FIG. 2 is a circuit diagram of each pixel in the photodetection device in FIG. 1. FIG. 3 is a plan view of each pixel in the photodetection device in FIG. 1. FIG. 4 is a cross-sectional view taken along section line IV-IV in FIG. 3. FIG. 5 is a cross-sectional view taken along section line V-V in FIG. 3. Note that FIG. 3 simply illustrates a photodiode, transistors, and wires included in the pixel.

A photodetection device 1 according to the present embodiment includes a substrate 2, multiple pixels 3, multiple power lines 7, multiple readout signal lines 8, and multiple reset signal lines 9. As illustrated in, for example, FIG. 1, the pixels 3 are in rows and columns on a main surface 2a of the substrate 2.

The photodetection device 1 may further include a drive circuit 4. The drive circuit 4 may generate a control signal to be provided to each of the pixels 3 and read a detection signal (voltage signal) from each of the pixels 3. As illustrated in, for example, FIG. 1, the drive circuit 4 may be located on the main surface 2a of the substrate 2. The drive circuit 4 may include, for example, an IC or an LSI circuit. The drive circuit 4 may be mounted on the main surface 2a of the substrate 2 by, for example, chip on glass (COG). The drive circuit 4 may be a thin film circuit formed on the main surface 2a by thin film formation such as chemical vapor deposition (CVD).

The substrate 2 is made of, for example, a glass material, a resin material, or a ceramic material. Examples of the glass material used for the substrate 2 include borosilicate glass, crystallized glass, and quartz. Examples of the resin material used for the substrate 2 include an epoxy resin, a polyimide resin, a polyamide resin, an acrylic resin, and a polycarbonate resin. Examples of the ceramic material used for the substrate 2 include alumina (Al₂O₃), zirconia (ZrO₂), silicon nitride (Si₃N₄), silicon carbide (SiC), and aluminum nitride (AlN).

The multiple power lines 7 are wires for providing a power supply voltage VDD to the multiple pixels 3. The power lines 7 are connected to an external power supply (not illustrated). Each of the power lines 7 is located for the corresponding column of the pixels 3 and is connected to the pixels 3 in the column. The power lines 7 may be connected to the drive circuit 4 and connected to the external power supply through the drive circuit 4.

The multiple readout signal lines 8 are wires for reading voltage signals READ generated respectively by the pixels 3. Each of the readout signal lines 8 is located for the corresponding column of the pixels 3 and is connected to the pixels 3 in the column. The readout signal lines 8 are connected to the drive circuit 4.

The multiple reset signal lines 9 are wires for resetting the voltage signals READ from the pixels 3 in the respective rows. Each of the reset signal lines 9 is located for the corresponding row of the pixels 3 and is connected to the pixels 3 in the row. The reset signal lines 9 are connected to the drive circuit 4. Each of the reset signal lines 9 provides a reset signal GATE_RST generated by the drive circuit 4 to the pixels 3 in the corresponding row.

The multiple power lines 7, the multiple readout signal lines 8, and the multiple

reset signal lines 9 may be located between the substrate 2 and a first insulating layer 5, inside the first insulating layer 5, or on the first insulating layer 5. The power lines 7, the readout signal lines 8, the reset signal lines 9, and select signal lines 10 may be made of a metal such as tantalum (Ta), neodymium (Nd), tungsten (W), titanium (Ti), molybdenum (Mo), aluminum (Al), chromium (Cr), or silver (Ag) or an alloy of these.

Each of the pixels 3 includes the first insulating layer 5, a photodiode (PD) 6, an amplifier transistor 11, and a reset transistor 12.

The first insulating layer 5 is located on the main surface 2a of the substrate 2. The

first insulating layer 5 includes a first surface 5a facing the substrate 2, and a second surface 5b opposite to the first surface 5a. The first insulating layer 5 may be made of, for example, an inorganic insulating material such as silicon oxide (SiO₂) or silicon nitride (Si₃N₄), or an organic material such as an acrylic resin or a polycarbonate resin.

A photodiode 6 is located on the second surface 5b of the first insulating layer 5. The photodiode 6 includes a semiconductor layer 61, an anode electrode 62, and a cathode electrode 63. The semiconductor layer 61 includes a third surface 61a facing the second surface 5b of the first insulating layer 5, and a fourth surface 61b opposite to the third surface 61a. The anode electrode 62 is located on the fourth surface 61b of the semiconductor layer 61. The cathode electrode 63 is located on the third surface 61a of the semiconductor layer 61. The semiconductor layer 61 may be made of, for example, silicon (Si), germanium (Ge), gallium arsenide (GaAs), or indium gallium arsenide (InGaAs). The anode electrode 62 may be, for example, a transparent conductive layer made of an indium tin oxide (ITO) or an indium zinc oxide (IZO). The cathode electrode 63 may be a non-transmissive metal layer made of a metal such as Ta, Nd, W, Ti, Mo, Al, Cr, or Ag or an alloy of these metals.

The photodiode 6 may be a PN photodiode or a PIN photodiode. In the photodetection device 1 according to the present embodiment, the photodiode 6 is a PIN photodiode, and the semiconductor layer 61 includes an intrinsic semiconductor layer (i-type semiconductor layer) 61e between a p-type semiconductor layer 61c and an n-type semiconductor layer 61d. A PIN photodiode has faster responsiveness and a smaller dark current than a PN photodiode.

The amplifier transistor 11 and the reset transistor 12 are each a three-terminal element including a gate electrode, an input electrode, and an output electrode. The amplifier transistor 11 and the reset transistor 12 may both be thin-film transistors (TFTs). In the photodetection device 1 according to the present embodiment, the amplifier transistor 11 and the reset transistor 12 are n-channel TFTs. The amplifier transistor 11 and the reset transistor 12 may be hereafter collectively referred to as TFTs 11 and 12.

The amplifier transistor 11 includes a gate electrode connected to the cathode electrode 63, an input electrode (drain electrode) connected to one power line 7a of the multiple power lines 7, and an output electrode (source electrode) connected to one readout signal line 8a of the multiple readout lines 8.

The reset transistor 12 includes a gate electrode connected to one reset signal line 9a of the multiple reset signal lines 9, an input electrode (drain electrode) connected to the power line 7a, and an output electrode (source electrode) connected to the cathode electrode 63 and the gate electrode of the amplifier transistor 11. The input electrode of the amplifier transistor 11 and the input electrode of the reset transistor 12 are both connected to the power line 7a.

As illustrated in, for example, FIG. 4, the TFTs 11 and 12 may each include a gate electrode 15, a gate insulating layer 16, a semiconductor layer 17, a source electrode 18, and a drain electrode 19. The gate electrode 15 is located on the main surface 2a of the substrate 2. The gate insulating layer 16 is made of, for example, SiO₂, and covers the main surface 2a of the substrate 2 and the gate electrode 15. The semiconductor layer 17 is located on the gate insulating layer 16 and covers the gate electrode 15. The semiconductor layer 17 is made of, for example, low-temperature polycrystalline silicon (LTPS). The semiconductor layer 17 includes channel region (also referred to as a channel) 17a located immediately above the gate electrode 15, a source region 17b located at one end of the channel 17a, and a drain region 17c located at the other end of the channel 17a. The source region 17b and the drain region 17c are made of, for example, n+LTPS. The semiconductor layer 17 may include a lightly doped drain (LDD) region between the channel 17a and the source region 17b, and between the channel 17a and the drain region 17c. The source electrode 18 and the drain electrode 19 are made of, for example, a metal such as tantalum (Ta), neodymium (Nd), tungsten (W), titanium (Ti), molybdenum (Mo), aluminum (Al), chromium (Cr), or silver (Ag) or an alloy of these. The source electrode 18 is connected to the source region 17b. The drain electrode 19 is connected to the drain region 17c. The source electrode 18 and the drain electrode 19 each are connected to, for example, the power line 7a, the readout signal line 8a, the reset signal line 9a, or a connection wire in each of the pixels 3. The source electrode 18 and the drain electrode 19 may each be formed integrally with the corresponding wire.

As illustrated in, for example, FIGS. 4 and 5, each of the pixels 3 includes a passivation film 24 covering the TFTs 11 and 12 and the gate insulating layer 16, and an insulating film 25 covering the passivation film 24. The passivation film 24 may be made of, for example, silicon oxide (SiO₂) or silicon nitride (Si₃N₄). The insulating film 25 may be made of, for example, an acrylic resin or a polycarbonate resin.

The semiconductor layer 17 may be made of, for example, amorphous silicon (a-Si) or indium gallium zinc oxide in place of LTPS. The TFTs 11 and 12 illustrated in FIGS. 4 and 5 are bottom-gated (inverted staggered), but the TFTs 11 and 12 may be top-gated (staggered).

In each of the pixels 3, a light reception voltage V_{PD} corresponding to the electric charge stored in the photodiode 6 is generated at the gate electrode of the amplifier transistor 11. The amplifier transistor 11 is a source follower transistor that amplifies the light reception voltage V_{PD} and outputs the amplified light reception voltage V_{PD} as a voltage signal READ to the readout signal line 8a. The gate electrode of the amplifier transistor 11 is connected to the output electrode of the reset transistor 12. Thus, after the amplifier transistor 11 outputs the voltage signal READ for one frame, setting the reset signal GATE_RST to a high (H) state and setting the reset transistor 12 to a conductive (ON) state resets the light reception voltage V_{PD} and resets the voltage signal READ.

As illustrated in, for example, FIGS. 3 and 4, each of the pixels 3 further includes a first contact hole 14. The first contact hole 14 extends through the first insulating layer 5 in the thickness direction from the second surface 5b to the first surface 5a, thus electrically connecting the cathode electrode 63 to the gate electrode of the amplifier transistor 11 and to the output electrode of the reset transistor 12. As illustrated in, for example, FIG. 3, the first contact hole 14 is located between the amplifier transistor 11 and the reset transistor 12 in a direction in which the power lines 7 extend (vertical direction in FIG. 3).

In the photodetection device 1, elements in each of the pixels 3 (e.g., the photodiode 6, the amplifier transistor 11, and the reset transistor 12) and wires (e.g., the power line 7a, the readout signal line 8a, and the reset signal line 9a) can be arranged efficiently. This can reduce a pixel pitch P between the pixels 3 to allow the photodetection device 1 to have higher definition.

As illustrated in, for example, FIG. 4, the first contact hole 14 may include a conductor layer 14a located on an inner surface of a recess 5c in a predetermined portion of the first insulating layer 5, and a filler 14b filling the recess 5c (specifically, a space surrounded by the conductor layer 14a). The recess 5c may be formed by dry etching or another etching method. The dry etching method used to form the recess 5c may be, for example, a reactive ion etching method. The conductor layer 14a may be made of a metal such as Ta, Nd, W, Ti, Mo, Al, Cr, or Ag or an alloy of these metals. As illustrated in, for example, FIG. 4, the conductor layer 14a may be a portion of the cathode electrode 63 of the photodiode 6 received in the recess 5c. The filler in the recess 5c may be of an organic material such as an acrylic resin, a silicone resin, a polyimide, a polyimide amide, benzocyclobutene, polysiloxane, or polysilazane, or of a photosensitive organic resin or a thermosetting resin. As illustrated in, for example, FIG. 4, the filler 14b may be a portion of the n-type semiconductor layer 61d and a portion of the intrinsic semiconductor layer 61e received in the recess 5c.

The photodetection device 1 may further include multiple select signal lines 10. The select signal lines 10 are wires for setting (selecting) readout periods for the respective voltage signals READ generated by the corresponding pixels 3. Each of the select signal lines 10 is located for the corresponding row of the pixels 3 and is connected to the pixels 3 in the row. The select signal lines 10 are connected to the drive circuit 4. Each of the select signal line 10 provides a reset signal GATE_RS generated by the drive circuit 4 to the pixels 3 in the corresponding row.

Each of the pixels 3 may include a select transistor 13. The select transistor 13 may be a three-terminal element including a gate electrode, an input electrode, and an output electrode. The select transistor 13 may be an n-channel TFT in the same manner as or in a similar manner to the amplifier transistor 11 and the reset transistor 12. The amplifier transistor 11, the reset transistor 12, and the select transistor 13 may be hereafter collectively referred to as TFTs 11, 12, and 13.

The select transistor 13 may include a gate electrode connected to one select signal line 10a of the multiple select signal lines 10, an input electrode (drain electrode) connected to the output electrode of the amplifier transistor 11, and an output electrode (source electrode) connected to the readout signal line 8a. The output electrode of the amplifier transistor 11 may not be directly connected to the readout signal line 8a, but may be connected to the readout signal line 8a through the select transistor 13. In each of the pixels 3, the voltage signal READ is read and output to the readout signal line 8a during a period in which the reset signal GATE_RS is high (H) and the select transistor 13 is in a conductive (ON) state. Thus, for each of the rows of the multiple pixels 3, the voltage signal READ generated by the pixel 3 in the corresponding row can be read.

As illustrated in, for example, FIG. 5, the amplifier transistor 11 and the select transistor 13 may share the semiconductor layer 17. This can eliminate the output electrode (source electrode) of the amplifier transistor 11, the input electrode (drain electrode) of the select transistor 13, and a wire connecting the output electrode of the amplifier transistor 11 to the input electrode of the select transistor 13. This reduces the area of each of the pixels 3 and the pixel pitch P to allow the photodetection device 1 to have higher definition.

The photodiode 6 may overlap the TFTs 11, 12, and 13 and the first contact hole 14 in a plan view. Thus, the photodiode 6, the TFTs 11, 12, and 13, and the first contact hole 14 can be arranged more efficiently to reduce the pixel pitch P. This allows the photodetection device 1 to have higher definition.

As illustrated in, for example, FIGS. 4 and 5, each of the pixels 3 may further include a second insulating layer 20, a bias line 21, and a second contact hole 22.

The second insulating layer 20 is located on the second surface 5b of the first insulating layer 5 and on the photodiode 6 and covers the first insulating layer 5 and the photodiode 6. The second insulating layer 20 includes a fifth surface 20a facing the photodiode 6, and a sixth surface 20b opposite to the fifth surface 20a. The second insulating layer 20 may be, for example, an inorganic insulating layer of, for example, silicon oxide (SiO₂) or silicon nitride (Si₃N₄), or an organic insulating layer of, for example, an acrylic resin or a polycarbonate resin.

The bias line 21 is a wire for applying a bias voltage to the anode electrode 62 of the photodiode 6. The bias line 21 is located on the sixth surface 20b of the second insulating layer 20. The bias line 21 is electrically connected to the external power supply (not illustrated). The bias line 21 may be connected to the drive circuit 4 and connected to the external power supply through the drive circuit 4. The bias line 21 may be made of a metal such as Ta, Nd, W, Ti, Mo, Al, Cr, or Ag or an alloy of these metals.

The second contact hole 22 extends through the second insulating layer 20 in the thickness direction from the sixth surface 20b to the fifth surface 20a, thus electrically connecting the bias line 21 to the anode electrode 62. As illustrated in, for example, FIG. 5, the second contact hole 22 may include a conductor layer 22a located on an inner surface of a recess 20c in a predetermined portion of the second insulating layer 20, and a filler 22b filling a space surrounded by the conductor layer 22a. The recess 20c may be formed by dry etching or another etching method. The dry etching method used to form the recess 20c may be, for example, a reactive ion etching method. The conductor layer 22a may be a transparent conductive layer of, for example, ITO or IZO. The conductor layer 22a may extend from inside the recess 20c to the sixth surface 20b and be connected to the bias line 21. The filler 22b may be made of an inorganic material such as silicon oxide (SiO₂) or silicon nitride (Si₃N₄), or an organic material such as an acrylic resin, a silicone resin, a polyimide, a polyimide amide, benzocyclobutene, polysiloxane, or polysilazane.

The first contact hole 14 and the second contact hole 22 may not overlap each other in a plan view. The photodiode 6 is fabricated by sequentially stacking a metal layer to be the cathode electrode 63, the semiconductor layer 61, and a transparent conductive layer to be the anode electrode 62 on the first contact hole 14. Thus, an upper surface of the photodiode 6 (a surface adjacent to the second insulating layer 20) unavoidably includes a recessed portion corresponding to the shape of the first contact hole 14. Thus, when the second contact hole 22 overlapping the first contact hole 14 is formed by an etching method, a resist used in the etching process may be left in the recessed portion and may lower the reliability of electrical connection between the anode electrode 62 and the conductor layer 22a. The first contact hole 14 and the second contact hole 22 without overlapping each other allow the anode electrode 62 and the conductor layer 22a to be connected reliably, thus increasing the reliability of the photodetection device 1.

In the photodetection device 1, the amplifier transistor 11 may include a channel overlapping the power line 7a in a plan view. During the operation of the photodetection device 1, a potential difference between the anode electrode 62 and the cathode electrode 63 generates an electric field E in the semiconductor layer 61. The electric field E can affect carrier density, carrier mobility, and other characteristics of the channel of the amplifier transistor 11, and can cause fluctuations in the voltage signal READ output from the amplifier transistor 11. The channel of the amplifier transistor 11 overlapping the power line 7a in a plan view can reduce the effect of the electric field E on the voltage signal READ. This stabilizes the voltage signal READ, thus improving the detection accuracy of the photodetection device 1.

In the photodetection device 1, the select transistor 13 may include a channel overlapping the readout signal line 8a in a plan view. This reduces the effect of the electric field E on carrier density, carrier mobility, and other characteristics of the channel of the select transistor 13, thus allowing the period in which the voltage signal READ is output from the amplifier transistor 11 to be set (selected) with higher accuracy. This improves the detection accuracy of the photodetection device 1.

In the photodetection device 1, the reset transistor 12 may include a channel overlapping at least one of the power line 7a or a wiring layer connected to the anode electrode 62 or the cathode electrode 63 in a plan view. This reduces the effect of the electric field E on carrier density, carrier mobility, and other characteristics of the channel of the reset transistor 12, thus allowing the light reception voltage V_{PD}, or specifically, the voltage signal READ, at the gate electrode of the amplifier transistor 11 to be reset reliably. This improves the detection accuracy of the photodetection device 1.

The TFTs 11, 12, and 13 may be bottom-gated. The substrate 2 may contain impurities that may, once entering the semiconductor layer of the TFT 11, 12, or 13, change the operating characteristics of the TFT 11, 12, or 13. The bottom-gated TFTs 11, 12, and 13 can reduce the likelihood of impurities in the substrate 2 entering the semiconductor layer of the TFT 11, 12, or 13. This can improve the detection accuracy of the photodetection device 1.

The power line 7a may have a larger dimension than the semiconductor layer in the amplifier transistor 11 in a width direction of the channel of the amplifier transistor 11. This effectively reduces the effect of the electric field E on the voltage signal READ.

The readout signal line 8a may have a larger dimension than the semiconductor layer in the select transistor 13 in a width direction of the channel of the select transistor 13. This effectively reduces the effect of the electric field E on the operation of the select transistor 13.

At least one of the power line 7a or the wiring layer connected to the anode electrode 62 or the cathode electrode 63 may have a larger dimension than the semiconductor layer in the reset transistor 12 in a width direction of the channel of the reset transistor 12. This effectively reduces the effect of the electric field E on the operation of the reset transistor 12.

As illustrated in, for example, FIGS. 4 and 5, each of the pixels 3 may further include a third insulating layer 23. The third insulating layer 23 may be located on the sixth surface 20b of the second insulating layer 20 and cover the bias line 21 and the second contact hole 22. This increases the reliability of connection between the bias line 21 and the second contact hole 22, thus increasing the reliability of the photodetection device 1. The third insulating layer 23 may be an inorganic insulating layer of, for example, silicon oxide (SiO₂) or silicon nitride (Si₃N₄), or an organic insulating layer of, for example, an acrylic resin, a polyimide resin, or a polycarbonate resin.

A photodetection device according to another embodiment of the present disclosure will now be described. A photodetection device 1A according to the present embodiment basically has the same structure as or a similar structure to the photodetection device 1 according to the embodiment described above except that the pixels 3 may not include the first contact hole 14. The same or similar components will not be described in detail.

In the present embodiment, as illustrated in, for example, FIG. 1, the photodetection device 1A includes the substrate 2, the multiple pixels 3, the multiple power lines 7, the multiple readout signal lines 8, the multiple reset signal lines 9, and the multiple select signal lines 10.

As illustrated in, for example, FIG. 2, each of the pixels 3 includes the photodiode 6, the amplifier transistor 11, the reset transistor 12, and the select transistor 13. The amplifier transistors 11, the reset transistors 12, and the select transistors 13 are bottom-gated n-channel TFTs. The amplifier transistor 11, the reset transistor 12, and the select transistor 13 may be hereafter collectively referred to as the TFTs 11, 12, and 13. The photodiode 6 and the TFTs 11, 12, and 13 are connected to the power line 7a, the readout signal line 8a, the reset signal line 9a, and the select signal line 10a in the same manner as or in a similar manner to the photodetection device 1.

In the photodetection device 1A, the cathode electrode 63 of the photodiode 6 may not be connected to the gate electrode of the amplifier transistor 11 and to the output electrode of the reset transistor 12 through the first contact hole 14. In the photodetection device 1A, the cathode electrode 63 may be connected to the gate electrode of the amplifier transistor 11 and to the output electrode of the reset transistor 12 through a contact hole that is not located between the amplifier transistor 11 and the reset transistor 12 in a direction in which the power line 7a extends.

In the photodetection device 1A, the channel of the amplifier transistor 11 overlaps the power line 7a in a plan view. During the operation of the photodetection device 1A, a potential difference between the anode electrode 62 and the cathode electrode 63 generates an electric field E in the semiconductor layer 61. The electric field E can affect carrier density, carrier mobility, and other characteristics of the channel of the amplifier transistor 11, and can cause fluctuations in the voltage signal READ output from the amplifier transistor 11. The channel of the amplifier transistor 11 overlapping the power line 7a in a plan view can reduce the effect of the electric field E on the voltage signal READ. This stabilizes the voltage signal READ, thus improving the detection accuracy of the photodetection device 1A.

In the photodetection device 1A, the channel of the select transistor 13 overlaps the readout signal line 8a in a plan view. This reduces the effect of the electric field E on carrier density, carrier mobility, and other characteristics of the channel of the select transistor 13, thus allowing the period in which the voltage signal READ is output from the amplifier transistor 11 to be set (selected) with higher accuracy. This improves the detection accuracy of the photodetection device 1A.

In the photodetection device 1A, the channel of the reset transistor 12 overlaps at least one of the power line 7a or the wiring layer connected to the anode electrode 62 or the cathode electrode 63 in a plan view. This reduces the effect of the electric field E on carrier density, carrier mobility, and other characteristics of the channel of the reset transistor 12, thus allowing the light reception voltage (specifically, the voltage signal READ) at the gate electrode of the amplifier transistor 11 to be reset reliably. This improves the detection accuracy of the photodetection device 1A.

The substrate 2 may contain impurities that may, once entering the semiconductor layer of the TFT 11, 12, or 13, change the operating characteristics of the TFT 11, 12, or 13. The bottom-gated TFTs 11, 12, and 13 can reduce the likelihood of impurities in the substrate 2 entering the semiconductor layer of the TFT 11, 12, or 13. This stabilizes the characteristics of the TFTs 11, 12, and 13, thus improving the detection accuracy of the photodetection device 1.

The power line 7a may have a larger dimension than the semiconductor layer in the amplifier transistor 11 in the width direction of the channel of the amplifier transistor 11. This effectively reduces the effect of the electric field E on the voltage signal READ. This further improves the detection accuracy of the photodetection device 1A.

The readout signal line 8a may have a larger dimension than the semiconductor layer in the select transistor 13 in the width direction of the channel of the select transistor 13. This effectively reduces the effect of the electric field E on the operation of the select transistor 13. This further improves the detection accuracy of the photodetection device 1A.

At least one of the power line 7a or the wiring layer connected to the anode electrode 62 or the cathode electrode 63 may have a larger dimension than the semiconductor layer in the reset transistor 12 in the width direction of the channel of the reset transistor 12. This effectively reduces the effect of the electric field E on the operation of the reset transistor 12. This further improves the detection accuracy of the photodetection device 1A.

The power line 7a, the readout signal line 8a, and the wiring layer connected to the anode electrode 62 or the cathode electrode 63 may be a non-transmissive metal layer. This reduces the likelihood of the operation of the photodiode 6 being unstable due to stray light entering the semiconductor layer through the substrate 2. This improves the detection accuracy of the photodetection device 1A.

The photodetection devices 1 and 1A may be usable for a sample observation apparatus for observing samples, such as animal cells, plant cells, yeast cells, or bacterial cells. The sample observation apparatus may include a container for containing a sample, a light source for emitting light toward the sample, and a photodetection device 1 or 1A for detecting a portion of light scattered by the sample. The sample observation apparatus including the photodetection device 1 or 1A allows accurate observation of samples.

The photodetection device 1 or 1A may be usable for a radiological image forming device. The radiological image forming device may include a scintillator that converts radiation such as X-rays, y-rays, and x-rays to light with a wavelength detectable with the photodiode 6, and the photodetection device 1 or 1A. The scintillator may be made of, for example, CsI:Tl or GOS (Gd₂O₂S:Tb). The radiological image forming device including the photodetection device 1 or 1A allows formation of radiological images with high definition and low noise. The photodetection device 1 or 1A may be usable for a medical photodetection device (also referred to as an X-ray apparatus). The X-ray apparatus may include a scintillator that converts X-rays to light with a wavelength detectable with the photodiode 6, and the photodetection device 1 or 1A. The X-ray apparatus including the photodetection device 1 or 1A allows formation of X-ray images with high definition and low noise.

In one or more embodiments of the present disclosure, the photodetection device includes pixels with their components arranged efficiently, achieving a smaller pixel pitch and higher definition. In one or more embodiments of the present disclosure, the photodetection device can obtain stable voltage signal output from the pixels, improving the detection accuracy of the photodetection device.

The photodetection device according to one or more embodiments of the present disclosure may have aspects (1) to (7) described below.

(1) A photodetection device, comprising:
a substrate;
a plurality of pixels in rows and columns on the substrate;
a plurality of power lines each located for a corresponding column of the columns of the plurality of pixels;
a plurality of readout signal lines each located for a corresponding column of the columns of the plurality of pixels, the plurality of readout signal lines being configured to read voltage signals generated respectively by the plurality of pixels; and
a plurality of reset signal lines each located for a corresponding row of the rows of the plurality of pixels, each of the plurality of reset signal lines being configured to reset voltage signals from pixels of the plurality of pixels in a corresponding row of the rows,
each of the plurality of pixels including
   a first insulating layer on the substrate,
   a photodiode on a second surface of the first insulating layer, the second surface being opposite to a first surface of the first insulating layer facing the substrate, the photodiode including a semiconductor layer, an anode electrode, and a cathode electrode,
   an amplifier transistor between the substrate and the first insulating layer, the amplifier transistor including a gate electrode connected to the cathode electrode, an input electrode connected to one power line of the plurality of power lines, and an output electrode connected to one readout signal line of the plurality of readout signal lines,
   a reset transistor between the substrate and the first insulating layer, the reset transistor including a gate electrode connected to one reset signal line of the plurality of reset signal lines, an input electrode connected to the one power line, and an output electrode connected to the cathode electrode and the gate electrode of the amplifier transistor, and
   a contact hole extending through the first insulating layer in a thickness direction and connecting the cathode electrode to the gate electrode of the amplifier transistor and to the output electrode of the reset transistor, the contact hole being located between the amplifier transistor and the reset transistor in a direction in which the one power line extends.

(2) The photodetection device according to (1), further comprising:
a plurality of select signal lines each located for a corresponding row of the rows of the plurality of pixels, the plurality of select signal lines being configured to set readout periods for the respective voltage signals,
wherein each of the plurality of pixels further includes a select transistor between the substrate and the first insulating layer, and the each of the plurality of pixels includes a gate electrode connected to one select signal line of the plurality of signal lines, an input electrode connected to the output electrode of the amplifier transistor, and an output electrode connected to the one readout signal line, and
the amplifier transistor and the select transistor share a semiconductor layer.

(3) The photodetection device according to (2), wherein
the photodiode overlaps the amplifier transistor, the reset transistor, the select transistor, and the contact hole in a plan view.

(4) The photodetection device according to any one of (1) to (3), wherein
the anode electrode is a transparent conductive layer located on a fourth surface of the semiconductor layer in the photodiode, and the fourth surface is opposite to a third surface of the semiconductor layer facing the substrate, and
the cathode electrode is a non-light-transmissive metal layer located on the third surface.

(5) The photodetection device according to any one of (1) to (4), wherein
each of the plurality of pixels further includes
   a second insulating layer covering the photodiode,
   a bias line located on a sixth surface of the second insulating layer opposite to a fifth surface of the second insulating layer facing the photodiode, the bias line being configured to apply a bias voltage to the photodiode, and
   a second contact hole extending through the second insulating layer in a thickness direction and electrically connecting the bias line to the anode electrode, and
the first contact hole and the second contact hole have no overlap in a plan view.

(6) The photodetection device according to (2), wherein
the amplifier transistor includes a channel overlapping the one power line in a plan view,
the select transistor includes a channel overlapping the one readout signal line in a plan view, and
the reset transistor includes a channel overlapping at least one of the one power line or a wiring layer connected to the anode electrode or the cathode electrode in a plan view.

The photodetection device according to one or more embodiments of the present disclosure may have aspects (7) to (9) described below.

(7) A photodetection device, comprising:
a substrate;
a plurality of pixels in rows and columns on the substrate;
a plurality of power lines each located for a corresponding column of the columns of the plurality of pixels;
a plurality of readout signal lines each located for a corresponding column of the columns of the plurality of pixels, the plurality of readout signal lines being configured to read voltage signals generated respectively by the plurality of pixels;
a plurality of reset signal lines each located for a corresponding row of the rows of the plurality of pixels, each of the plurality of reset signal lines being configured to reset voltage signals from pixels of the plurality of pixels in a corresponding row of the rows; and
a plurality of select signal lines each located for a corresponding row of the rows of the plurality of pixels, the plurality of select signal lines being configured to set readout periods for the respective voltage signals,
each of the plurality of pixels including
   a photodiode including an anode electrode and a cathode electrode,
   an amplifier transistor including a gate electrode connected to the cathode electrode and an input electrode connected to one power line of the plurality of power lines,
   a reset transistor including a gate electrode connected to one reset signal line of the plurality of reset signal lines, an input electrode connected to the one power line, and an output electrode connected to the cathode electrode and the gate electrode of the amplifier transistor, and
   a select transistor including a gate electrode connected to one select signal line of the plurality of select signal lines, an input electrode connected to the output electrode of the amplifier transistor, and an output electrode connected to one readout signal line of the plurality of readout signal lines,
the amplifier transistor including a channel overlapping the one power line in a plan view,
the select transistor including a channel overlapping the one readout signal line in a plan view,
the reset transistor including a channel overlapping at least one of the one power line or a wiring layer connected to the anode electrode or the cathode electrode.

(8) The photodetection device according to (7), wherein
the one power line has a larger dimension than a semiconductor layer in the amplifier transistor in a width direction of the channel of the amplifier transistor,
the one readout signal line has a larger dimension than a semiconductor layer in the select transistor in the width direction of the channel of the select transistor, and
at least the one of the one power line or the wiring layer connected to the anode electrode or the cathode electrode has a larger dimension than a semiconductor layer in the reset transistor in the width direction of the channel of the reset transistor.

(9) The photodetection device according to (7) or (8), wherein
each of the one power line, the one readout signal line, and the wiring layer connected to the anode electrode or the cathode electrode is a metal layer.

Although the photodetection devices according to the embodiments of the present disclosure have been described in detail, the photodetection devices according to the embodiments of the present disclosure are not limited to those in the above embodiments, and may be changed or varied in various manners without departing from the spirit and scope of the present disclosure. The components described in the above embodiments may be entirely or partially combined as appropriate unless any contradiction arises.

### REFERENCE SIGNS

1 photodetection device
1A photodetection device
2 substrate
2a main surface
3 pixel
4 drive circuit
5 first insulating layer
5a first surface
5b second surface
5c recess
6 photodiode
61 semiconductor layer
61a third surface
61b fourth surface
61c p-type semiconductor layer
61d n-type semiconductor layer
61e intrinsic semiconductor layer
62 anode electrode
63 cathode electrode
7,7a power line
8, 8a readout signal line
9, 9a reset signal line
10, 10a select signal line
11 amplifier transistor
12 reset transistor
13 select transistor
14 first contact hole
14a conductor layer
14b filler
15 gate electrode
16 gate insulating layer
17 semiconductor layer
17a channel region (channel)
17b source region
17c drain region
17d LDD region
18 source electrode
19 drain electrode
20 second insulating layer
20a fifth surface
20b sixth surface
20c recess
21 bias line
22 second contact hole
22a conductor layer
22b filler
23 third insulating layer
24 passivation film
25 insulating film

1. A photodetection device, comprising:
a substrate;
a plurality of pixels in rows and columns on the substrate;
a plurality of power lines each located for a corresponding column of the columns of the plurality of pixels;
a plurality of readout signal lines each located for a corresponding column of the columns of the plurality of pixels, the plurality of readout signal lines being configured to read voltage signals generated respectively by the plurality of pixels; and
a plurality of reset signal lines each located for a corresponding row of the rows of the plurality of pixels, each of the plurality of reset signal lines being configured to reset voltage signals from pixels of the plurality of pixels in a corresponding row of the rows,
each of the plurality of pixels including
a first insulating layer on the substrate,
a photodiode on a second surface of the first insulating layer, the second surface being opposite to a first surface of the first insulating layer facing the substrate, the photodiode including a semiconductor layer, an anode electrode, and a cathode electrode,
an amplifier transistor between the substrate and the first insulating layer, the amplifier transistor including a gate electrode connected to the cathode electrode, an input electrode connected to one power line of the plurality of power lines, and an output electrode connected to one readout signal line of the plurality of readout signal lines,
a reset transistor between the substrate and the first insulating layer, the reset transistor including a gate electrode connected to one reset signal line of the plurality of reset signal lines, an input electrode connected to the one power line, and an output electrode connected to the cathode electrode and the gate electrode of the amplifier transistor, and
a contact hole extending through the first insulating layer in a thickness direction and connecting the cathode electrode to the gate electrode of the amplifier transistor and to the output electrode of the reset transistor, the contact hole being located between the amplifier transistor and the reset transistor in a direction in which the one power line extends.

2. The photodetection device according to claim 1, further comprising:
a plurality of select signal lines each located for a corresponding row of the rows of the plurality of pixels, the plurality of select signal lines being configured to set readout periods for the respective voltage signals,
wherein each of the plurality of pixels further includes a select transistor between the substrate and the first insulating layer, and the each of the plurality of pixels includes a gate electrode connected to one select signal line of the plurality of signal lines, an input electrode connected to the output electrode of the amplifier transistor, and an output electrode connected to the one readout signal line, and
the amplifier transistor and the select transistor share a semiconductor layer.

3. The photodetection device according to claim 2, wherein
the photodiode overlaps the amplifier transistor, the reset transistor, the select transistor, and the contact hole in a plan view.

4. The photodetection device according to claim 1, wherein
the anode electrode is a transparent conductive layer located on a fourth surface of the semiconductor layer in the photodiode, and the fourth surface is opposite to a third surface of the semiconductor layer facing the substrate, and
the cathode electrode is a non-light-transmissive metal layer located on the third surface.

5. The photodetection device according to claim 1, wherein
each of the plurality of pixels further includes
a second insulating layer covering the photodiode,
a bias line located on a sixth surface of the second insulating layer opposite to a fifth surface of the second insulating layer facing the photodiode, the bias line being configured to apply a bias voltage to the photodiode, and
a second contact hole extending through the second insulating layer in a thickness direction and electrically connecting the bias line to the anode electrode, and
the first contact hole and the second contact hole have no overlap in a plan view.

6. The photodetection device according to claim 2, wherein
the amplifier transistor includes a channel overlapping the one power line in a plan view,
the select transistor includes a channel overlapping the one readout signal line in a plan view, and
the reset transistor includes a channel overlapping at least one of the one power line or a wiring layer connected to the anode electrode or the cathode electrode in a plan view.

7. A photodetection device, comprising:
a substrate;
a plurality of pixels in rows and columns on the substrate;
a plurality of power lines each located for a corresponding column of the columns of the plurality of pixels;
a plurality of readout signal lines each located for a corresponding column of the columns of the plurality of pixels, the plurality of readout signal lines being configured to read voltage signals generated respectively by the plurality of pixels;
a plurality of reset signal lines each located for a corresponding row of the rows of the plurality of pixels, each of the plurality of reset signal lines being configured to reset voltage signals from pixels of the plurality of pixels in a corresponding row of the rows; and
a plurality of select signal lines each located for a corresponding row of the rows of the plurality of pixels, the plurality of select signal lines being configured to set readout periods for the respective voltage signals,
each of the plurality of pixels including
a photodiode including an anode electrode and a cathode electrode,
an amplifier transistor including a gate electrode connected to the cathode electrode and an input electrode connected to one power line of the plurality of power lines,
a reset transistor including a gate electrode connected to one reset signal line of the plurality of reset signal lines, an input electrode connected to the one power line, and an output electrode connected to the cathode electrode and the gate electrode of the amplifier transistor, and
a select transistor including a gate electrode connected to one select signal line of the plurality of select signal lines, an input electrode connected to the output electrode of the amplifier transistor, and an output electrode connected to one readout signal line of the plurality of readout signal lines,
the amplifier transistor including a channel overlapping the one power line in a plan view,
the select transistor including a channel overlapping the one readout signal line in a plan view,
the reset transistor including a channel overlapping at least one of the one power line or a wiring layer connected to the anode electrode or the cathode electrode.

8. The photodetection device according to claim 7, wherein
the one power line has a larger dimension than a semiconductor layer in the amplifier transistor in a width direction of the channel of the amplifier transistor,
the one readout signal line has a larger dimension than a semiconductor layer in the select transistor in the width direction of the channel of the select transistor, and
at least the one of the one power line or the wiring layer connected to the anode electrode or the cathode electrode has a larger dimension than a semiconductor layer in the reset transistor in the width direction of the channel of the reset transistor.

9. The photodetection device according to claim 7, wherein
each of the one power line, the one readout signal line, and the wiring layer connected to the anode electrode or the cathode electrode is a metal layer.
